(19) United States
(12) Patent Application Publication
(10) Pub. No.: US 2026/0223581 A1
(43) Pub. Date: Jul. 30, 2026

(54) DISPLAY SUBSTRATE, MANUFACTURING METHOD AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO. LTD., Beijing (CN)

(72) Inventor: Qian Li, Beijing (CN)

(73) Assignees: CHENGDU BOE OPTOELECTRONICS TECHNOLOGY CO., LTD., Chengdu, Sichuan (CN); BOE TECHNOLOGY GROUP CO. LTD., Beijing (CN)

(21) Appl. No.: 19/145,600

(22) PCT Filed: Jul. 8, 2024
(86) PCT No.: PCT/CN2024/104118

§ 371 Date: Jul. 3, 2025

(30) Foreign Application Priority Data
Aug. 30, 2023 (CN) 202311110229.6

(51) Int. Cl. H10K 59/80; H10K 59/12; H10K 59/38

(52) U.S. Cl. CPC H10K 59/8792; H10K 59/1201; H10K 59/38; H10K 59/879

(57) ABSTRACT

A display substrate includes: an array of light-emitting elements on a driving substrate; an encapsulation layer at a light-exiting side of the light-emitting element; and a black matrix structure at a side of the encapsulation layer away from the driving substrate. The black matrix structure includes at least two layers of first black matrix patterns arranged sequentially in a light-exiting direction of the light-emitting element. In the light-exiting direction of the light-emitting element, an orthogonal projection of an aperture region of the light-emitting element onto the driving substrate is arranged in a region defined by a first layer of the first black matrix pattern, and an orthogonal projection of a region defined by a former layer of the first black matrix pattern onto the driving substrate is arranged in an orthogonal projection of a region defined by a latter layer of the first black matrix pattern onto the driving substrate.

### CROSS-REFERENCE TO RELATED APPLICATION

This application claims a priority of the Chinese patent application No. 202311110229.6 filed on Aug. 30, 2023, which is incorporated herein by reference in its entirety.

### TECHNICAL FIELD

The present disclosure relates to the field of display technology, in particular to a display substrate, a manufacturing method and a display device.

### BACKGROUND

Organic Light-Emitting Diode (OLED) display device has already been regarded as a promising next-generation display technology due to such advantages as being light and thin, wide viewing angle, self-illumination, continuously-adjustable light-emitting color, low cost, rapid response, low power consumption, low driving voltage, wide operating temperature range, simple manufacture process, high luminous efficiency and being capable of achieving flexible display.

In the related art, the OLED display device has a same viewing angle in different directions at a light-exiting side, but in some scenarios, the OLED display device needs to have different view angles in different direction.

### SUMMARY

An object of the present disclosure is to provide a display substrate, a manufacturing method and a display device, so as to provide the display device with different viewing angles in different directions.

In order to solve the above-mentioned technical problem, the present disclosure provides the following technical solutions.

In one aspect, the present disclosure provides in some embodiments a display substrate, including: a driving substrate; a plurality of light-emitting elements arranged in an array on the driving substrate; an encapsulation layer arranged at a light-exiting side of the light-emitting element; and a black matrix structure arranged at a side of the encapsulation layer away from the driving substrate. The black matrix structure includes at least two layers of first black matrix patterns arranged sequentially in a light-exiting direction of the light-emitting element, and the first black matrix pattern extends in a first direction; wherein in the light-exiting direction of the light-emitting element, an orthogonal projection of an aperture region of the light-emitting element onto the driving substrate is arranged in a region defined by a first layer of the first black matrix pattern, and an orthogonal projection of a region defined by a former layer of the first black matrix pattern onto the driving substrate is arranged in an orthogonal projection of a region defined by a latter layer of the first black matrix pattern onto the driving substrate.

In some embodiments of the present disclosure, the black matrix structure includes three layers of the first black matrix patterns arranged sequentially in the light-exiting direction of the light-emitting element.

In some embodiments of the present disclosure, the black matrix structure further includes at least one layer of a second black matrix pattern arranged sequentially in the light-exiting direction of the light-emitting element, the second black matrix pattern extends in a second direction, an orthogonal projection of the aperture region of the light-emitting element onto the driving substrate is arranged in a region defined by the second black matrix pattern, the second direction intersects the first direction, and a quantity of layers of the second black matrix patterns is smaller than a quantity of layers of the first black matrix patterns.

In some embodiments of the present disclosure, the first direction is perpendicular to the second direction.

In some embodiments of the present disclosure, the black matrix structure includes three layers of the first black matrix patterns and one layer of the second black matrix pattern arranged sequentially in the light-exiting direction of the light-emitting element.

In some embodiments of the present disclosure, the first layer of the first black matrix pattern is arranged at a same layer as a first layer of the second black matrix pattern, the first layer of the first black matrix pattern and the first layer of the second black matrix pattern define a first region, and the orthogonal projection of the aperture region of the light-emitting element onto the driving substrate is arranged in an orthogonal projection of the first region onto the driving substrate.

In some embodiments of the present disclosure, the display substrate further includes a color film layer covering the aperture region of the light-emitting element, and the orthogonal projection of the light-emitting element onto the driving substrate is arranged in an orthogonal projection of the color film layer onto the driving substrate.

In some embodiments of the present disclosure, the display substrate further includes: a first refraction layer covering a region defined by a second layer of the first black matrix pattern, the first refraction layer being arranged at a side of an outermost layer of the first black matrix pattern close to the driving substrate; and a second refraction layer arranged at a side of the first refraction layer away from the driving substrate, a refractive index of the second refraction layer being greater than a refractive index of the first refraction layer.

In some embodiments of the present disclosure, a side surface of the first refraction layer has a gradient angle smaller than 50°.

In some embodiments of the present disclosure, the orthogonal projection of the color film layer onto the driving substrate is arranged in an orthogonal projection of the first refraction layer onto the driving substrate.

In some embodiments of the present disclosure, the first refraction layer includes a plurality of prism members arranged in an array, and adjacent prism members adjoin each other.

In some embodiments of the present disclosure, the prism member is of a hemispherical shape.

In some embodiments of the present disclosure, the display substrate further includes: a retaining wall structure arranged at a side of the color film layer away from the driving substrate, the retaining wall structure defining a second region, the orthogonal projection of the aperture region of the light-emitting element onto the driving substrate being arranged in an orthogonal projection of the second region onto the driving substrate, the retaining wall structure being arranged at a side of the outermost layer of the first black matrix pattern close to the driving substrate; and a third refraction layer arranged at a side of the retaining wall structure away from the driving substrate, a refractive index of the retaining wall structure being greater than a refractive index of the third refraction layer.

In some embodiments of the present disclosure, a longitudinal section of the retaining wall structure in a direction perpendicular to an extension direction of the retaining wall structure is a trapezoid.

In some embodiments of the present disclosure, the display substrate further includes: a fourth refraction layer arranged at a side of the color film layer away from the driving substrate, the fourth refraction layer being arranged at a side of the outermost layer of the first black matrix pattern close to the driving substrate; and a fifth refraction layer arranged at a side of the fourth refraction layer away from the driving substrate, a refractive index of the fifth refraction layer being greater than a refractive index of the fourth refraction layer.

In some embodiments of the present disclosure, the orthogonal projection of the color film layer onto the driving substrate is arranged in an orthogonal projection of the fourth refraction layer onto the driving substrate; and the orthogonal projection of the fourth refraction layer onto the driving substrate is arranged in an orthogonal projection of the fifth refraction layer onto the driving substrate.

In some embodiments of the present disclosure, the fourth refraction layer includes a first portion and a second portion laminated one on another in a direction away from the driving substrate, a cross section of the first portion in a direction perpendicular to the driving substrate is an inverted-trapezoid, and a cross section of the second portion in the direction perpendicular to the driving substrate is a trapezoid.

In some embodiments of the present disclosure, the display substrate further includes a sixth refraction layer arranged at a same layer as the first portion and surrounding the first portion, and a refractive index of the sixth refraction layer is greater than a refractive index of the first portion.

In some embodiments of the present disclosure, a lower base angle of the trapezoid is smaller than 50°.

In some embodiments of the present disclosure, the display substrate further includes: a seventh refraction layer arranged between two adjacent layers of the first black matrix patterns; and a transparent retaining wall extending in the first direction. A refractive index of the transparent retaining wall is smaller than a refractive index of the seventh refraction layer. The transparent retaining wall is arranged at two sides of the aperture region, and/or the transparent retaining wall is arranged at two sides of the region defined by the first black matrix pattern.

In some embodiments of the present disclosure, the transparent retaining wall includes: a first layer of the transparent retaining wall arranged at two sides of the aperture region of the light-emitting element; a second layer of the transparent retaining wall arranged at two sides of the region defined by the first layer of the first black matrix pattern; and a third layer of the transparent retaining wall arranged at two sides of a region defined by a second layer of the first black matrix pattern.

In another aspect, the present disclosure provides in some embodiments a display device including the above-mentioned display substrate.

In yet another aspect, the present disclosure provides in some embodiments a method for manufacturing a display substrate, including: providing a driving substrate; forming a plurality of light-emitting elements arranged in an array on the driving substrate; forming an encapsulation layer at a light-exiting side of the light-emitting element; and forming a black matrix structure at a side of the encapsulation layer away from the driving substrate. The black matrix structure includes at least two layers of first black matrix patterns arranged sequentially in a light-exiting direction of the light-emitting element, and the first black matrix pattern extends in a first direction. In the light-exiting direction of the light-emitting element, an orthogonal projection of an aperture region of the light-emitting element onto the driving substrate is arranged in a region defined by a first layer of the first black matrix patterns, and an orthogonal projection of a region defined by a former layer of the first black matrix patterns onto the driving substrate is arranged in an orthogonal projection of a region defined by a latter layer of the first black matrix patterns onto the driving substrate.

The present disclosure has the following beneficial effects.

In the embodiments of the present disclosure, at least two layers of the first black matrix patterns are arranged at the light-exiting side of the light-emitting element, the first black matrix pattern extends in the first direction, and light emitted by the light-emitting element in a direction intersecting the first direction is shielded by the first black matrix pattern. As a result, a viewing angle in the direction intersecting the first direction is narrowed, so that the light-emitting element is provided with a viewing angle in the first direction different from that in the other direction.

### BRIEF DESCRIPTION OF THE DRAWINGS

FIG. 1 is a schematic view showing requirements of a vehicle-mounted display product on viewing angles in different directions;

FIG. 2 is a schematic view showing an OLED display substrate in the related art;

FIG. 3 is a schematic view showing viewing angles of the OLED display substrate in different directions in the related art;

FIG. 4 is a top view of the OLED display substrate according to an embodiment of the present disclosure; and

FIGS. 5 to 16 are sectional views of the OLED display substrate according to an embodiment of the present disclosure.

### REFERENCE SIGN LIST

1 red subpixel
2 green subpixel
3 black matrix structure
4 blue subpixel
01 driving substrate
02 anode
03 pixel definition layer
04 light-emitting layer
05 cathode
06 first inorganic thin film
07 organic thin film
08 second inorganic thin film
09 polarizer
101 first layer of black matrix
102 second layer of black matrix
103 third layer of black matrix
11 planarization layer
12 color film layer
13 first refraction layer
141 first layer of refraction layer with a high refractive index
142 second layer of refraction layer with a high refractive index
143 third layer of refraction layer with a high refractive index
131 prism member
132 first layer of refraction layer with a low refractive index
133 second layer of refractive layer with a low refractive index.
143 retaining wall structure
134 first portion
135 second portion
112 first film layer
113 second film layer
144 sixth refraction layer
151 first layer of transparent retaining wall
152 second layer of transparent retaining wall
153 third layer of transparent retaining wall

### DETAILED DESCRIPTION

In order to make the objects, the technical solutions and the advantages of the present disclosure more apparent, the present disclosure will be described hereinafter in conjunction with the drawings and embodiments.

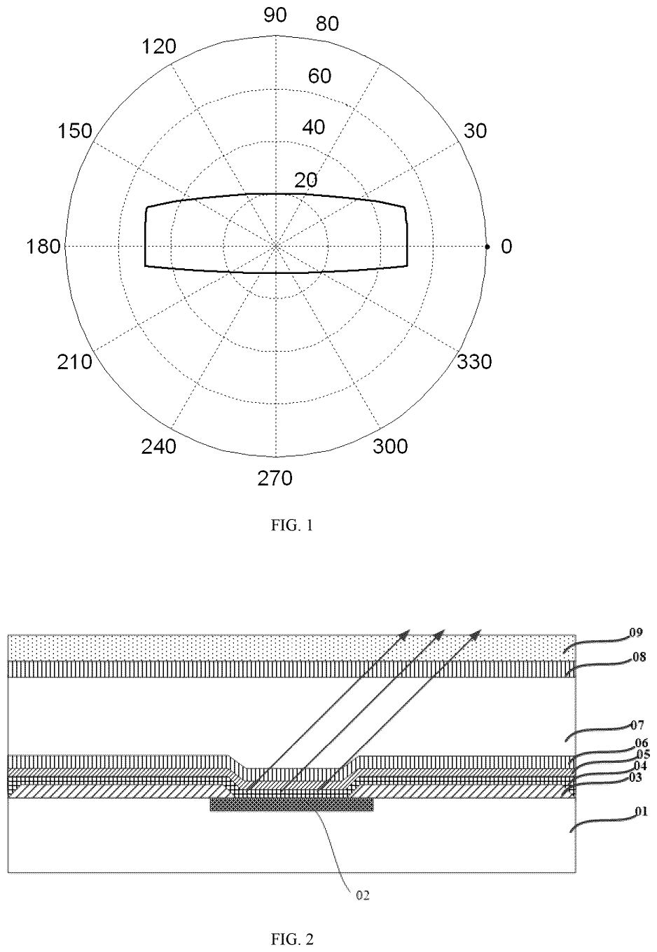

In some scenarios, an OLED display device needs to have different viewing angles in different directions. For example, for a vehicle-mounted display product, a small viewing angle needs to be provided in a vertical direction (direction V), so as to prevent the occurrence of an image caused in a case that light generated by the vehicle-mounted display panel reaches a front windshield, thereby to prevent the observation of an object in front of a vehicle from being adversely affected. In a horizontal direction (direction H), the vehicle-mounted display product needs to be provided with a wide viewing angle as possible, so as to facilitate user's observation and use. FIG. 1 is a schematic view showing the requirements of the vehicle-mounted display product on viewing angles in different directions, and different viewing angle ranges (indicated by a solid box in FIG. 1) are specified in the direction H and the direction V. In the direction V, the viewing angle needs to be narrowed, while in the direction H, the viewing angle needs to be broadened.

FIG. 2 is a schematic view showing an OLED display substrate in the related art. As shown in FIG. 2, the OLED display substrate includes a driving substrate 01, a pixel definition layer 03 arranged on the driving substrate 01, a light-emitting element arranged in a pixel region defined by the pixel definition layer 03 and including an anode 02, a light-emitting layer 04 and a cathode 05, an encapsulation layer arranged at a light-exiting side of the light-emitting element and including a first inorganic thin film 06, an organic thin film 07 and a second inorganic thin film 08 laminated one on another, and a polarizer 09 arranged at a side of the encapsulation layer away from the driving substrate. A propagation path of the light is not affected by the polarizer 09, so in different directions, the display device has a same viewing angle, and a viewing angle range is indicated by a circle in FIG. 3.

An object of the present disclosure is to provide a display substrate, a manufacturing method and a display device, so as to provide the display device with different viewing angles in different directions.

The present disclosure provides in some embodiments a display substrate, which includes: a driving substrate; a plurality of light-emitting elements arranged in an array on the driving substrate; an encapsulation layer arranged at a light-exiting side of the light-emitting element; and a black matrix structure arranged at a side of the encapsulation layer away from the driving substrate. The black matrix structure includes at least two layers of first black matrix patterns arranged sequentially in a light-exiting direction of the light-emitting element, and the first black matrix pattern extends in a first direction. In the light-exiting direction of the light-emitting element, an orthogonal projection of an aperture region of the light-emitting element onto the driving substrate is arranged in a region defined by a first layer of the first black matrix pattern, and an orthogonal projection of a region defined by a former layer of the first black matrix pattern onto the driving substrate is arranged in an orthogonal projection of a region defined by a latter layer of the first black matrix pattern onto the driving substrate.

In the embodiments of the present disclosure, at least one layer of the first black matrix pattern is arranged at the light-exiting side of the light-emitting element, the first black matrix pattern extends in the first direction, and light emitted by the light-emitting element in a direction intersecting the first direction is shielded by the first black matrix pattern. As a result, a viewing angle in the direction intersecting the first direction is narrowed, so that the light-emitting element is provided with a viewing angle in the first direction different from that in the other direction.

In the embodiments of the present disclosure, through adjusting a size of the region defined by the first black matrix pattern, the viewing angle in the direction intersecting the first direction is adjusted. The smaller the size of the region defined by the first black matrix pattern, the narrower the viewing angle in the direction intersecting the first direction; the larger the size of the region defined by the first black matrix pattern, the wider the viewing angle in the direction intersecting the first direction.

In some embodiments of the present disclosure, the black matrix structure further includes at least one layer of a second black matrix pattern arranged sequentially in the light-exiting direction of the light-emitting element, the second black matrix pattern extends in a second direction, an orthogonal projection of the aperture region of the light-emitting element onto the driving substrate is arranged in a region defined by the second black matrix pattern, the second direction intersects the first direction, and a quantity of layers of the second black matrix patterns is smaller than a quantity of layers of the first black matrix patterns.

In the embodiments of the present disclosure, at least one layer of the second black matrix pattern is further arranged at the light-exiting side of the light-emitting element, and the second black matrix pattern extends in the second direction. The light emitted by the light-emitting element in a direction intersecting the second direction is shielded by the second black matrix pattern, so as to narrow the viewing angle in the direction intersecting the second direction. In the embodiments of the present disclosure, through adjusting a size of the region defined by the second black matrix pattern, the viewing angle in the direction intersecting the second direction is adjusted. The smaller the size of the region defined by the second black matrix pattern, the narrower the viewing angle in the direction intersecting the second direction; the larger the size of the region defined by the second black matrix pattern, the wider the viewing angle in the direction intersecting the second direction.

In some embodiments of the present disclosure, the first direction is perpendicular to the second direction. In this way, through adjusting the size of the region defined by the second black matrix pattern, the viewing angle int eh first direction may be adjusted. The smaller the size of the region defined by the second black matrix pattern, the narrower the viewing angle in the first direction; the larger the size of the region defined by the second black matrix pattern, the wider the viewing angle in the first direction. Through adjusting the size of the region defined by the first black matrix pattern, the viewing angle in the second direction may be adjusted. The smaller the size of the region defined by the first black matrix pattern, the narrower the viewing angle in the second direction; the larger the size of the region defined by the first black matrix pattern, the wider the viewing angle in the second direction.

In the embodiments of the present disclosure, through adjusting the size of the region defined by the second black matrix pattern and/or the size of the region defined by the first black matrix pattern, it is able to adjust the viewing angle in the first direction and/or the second direction, thereby to provide a display device with different viewing angles in different directions, and meet the requirements on the viewing angles in different directions.

In the embodiments of the present disclosure, the quantity of layers of the first black matrix patterns and the layers of the second black matrix patterns may be set according to the practical need. In some embodiments of the present disclosure, in a case that the viewing angle in the first direction needs to be narrowed and the viewing angle in the second direction needs to be broadened, the black matrix structure includes three layers of the first black matrix patterns and one layer of the second black matrix pattern arranged sequentially in the light-exiting direction of the light-emitting element. Of course, the black matrix structure is not limited to three layers of the first black matrix patterns and one layer of the second black matrix pattern, and it may include more layers of the first black matrix patterns or more layers of the second black matrix patterns. Usually, the more the layers of the first black matrix patterns, the narrower the viewing angle in the second direction; the more the layers of the second black matrix patterns, the narrower the viewing angle in the first direction.

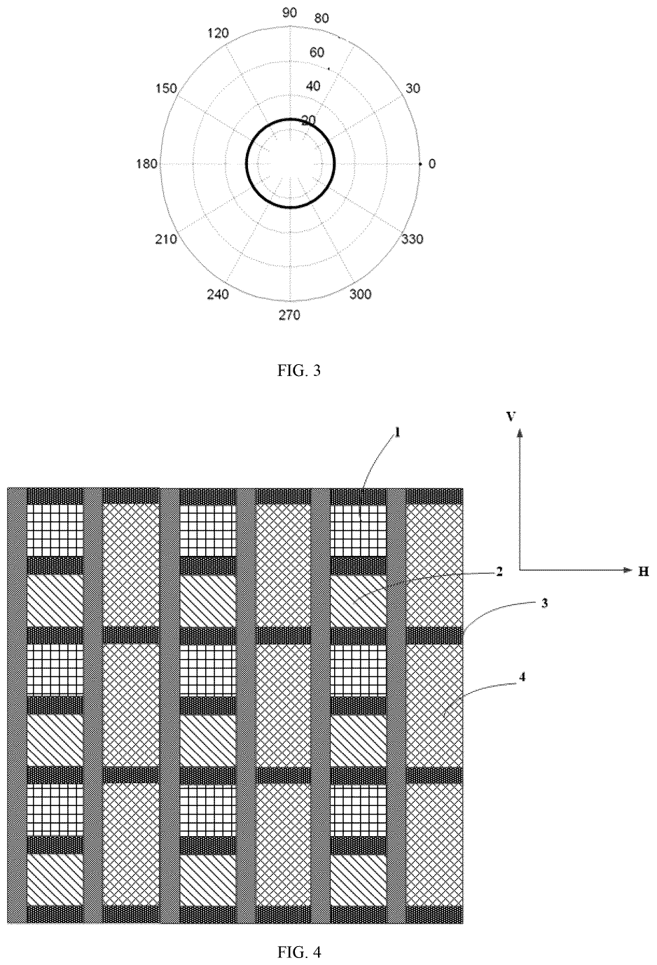

In some embodiments of the present disclosure, as shown in FIG. 4, the display substrate includes a plurality of subpixels arranged in an array and a black matrix structure 3. The plurality of subpixels includes a red subpixel 1, a green subpixel 2 and a green subpixel 4. In a case that the display substrate is applied to a vehicle-mounted display product, a narrow viewing angle needs to be provided in the direction V, and a wide viewing angle needs to be provided in the direction H.

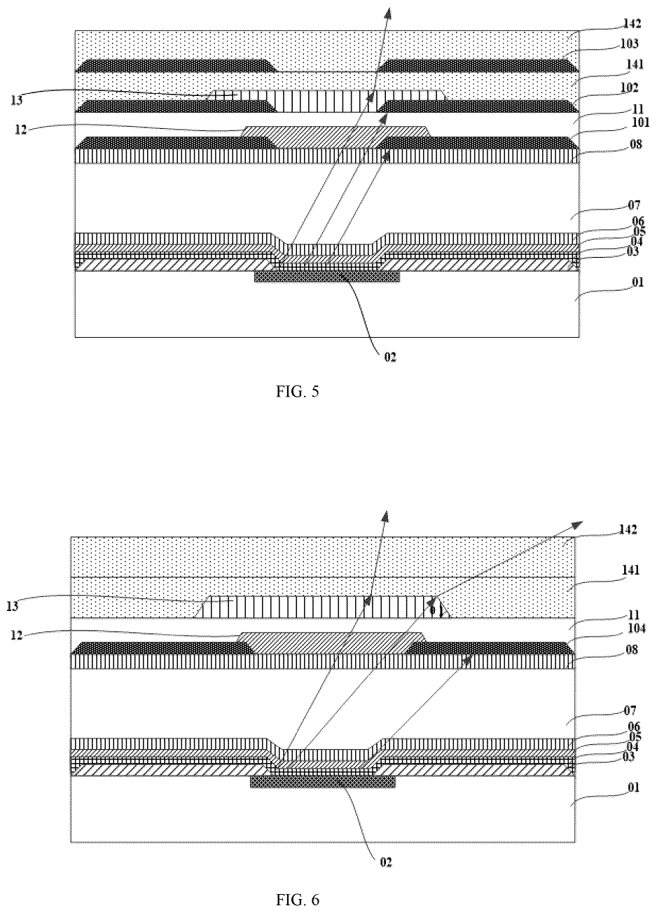

In a specific embodiment of the present disclosure, FIG. 5 is a sectional view of the display substrate in FIG. 4 in the direction H (i.e., the first direction), and FIG. 6 is a sectional view of the display substrate in FIG. 4 in the direction V (i.e., the second direction). As shown in FIGS. 4 and 5, the display substrate includes a driving substrate 01, a pixel definition layer 03 arranged on the driving substrate 01, a light-emitting element arranged in a pixel region defined by the pixel definition layer 03 and including an anode 02, a light-emitting layer 04 and a cathode 05, and an encapsulation layer arranged at a light-exiting side of the light-emitting element and including a first inorganic thin film 06, an organic thin film 07 and a second inorganic thin film 08 laminated one on another. As shown in FIG. 5, three layers of the first black matrix patterns are provided, i.e., a first layer of the first black matrix pattern 101, a second layer of the first black matrix pattern 102 and a third layer of the first black matrix pattern 103. A planarization layer 11 is arranged between the first layer of the first black matrix pattern 101 and the second layer of the first black matrix pattern 102. As shown in FIG. 6, one layer of the second black matrix pattern 104 is provided. The layer of the second black matrix pattern 104 is arranged at a same layer as the first layer of the first black matrix pattern 101, the first layer of the first black matrix pattern 101 and the layer of the second black matrix pattern 102 define a first region, a size of the first region is greater than a size of the aperture region of the light-emitting element, and the orthogonal projection of the aperture region of the light-emitting element onto the driving substrate is arranged in an orthogonal projection of the first region onto the driving substrate.

A size of the aperture region defined by the first layer of the first black matrix pattern 101 is smaller than a size of the aperture region defined by the second layer of the first black matrix pattern 102, and an orthogonal projection of the aperture region defined by the first layer of the first black matrix pattern 101 onto the driving substrate is arranged in an orthogonal projection of the aperture region defined by the second layer of the first black matrix pattern 102 onto the driving substrate. The size of the aperture region defined by the second layer of the first black matrix pattern 102 is smaller than a size of the aperture region defined by the third layer of the first black matrix pattern 103, and the orthogonal projection of the aperture region defined by the second layer of the first black matrix pattern 102 onto the driving substrate is arranged in an orthogonal projection of the aperture region defined by the third layer of the first black matrix pattern 103 onto the driving substrate.

The display substrate further includes a color film layer 12 covering the aperture region of the light-emitting element, and the orthogonal projection of the aperture region of the light-emitting element onto the driving substrate is arranged in an orthogonal projection of the color film layer 12 onto the driving substrate. Through the color film 12, it is able to achieve colorful display.

As shown in FIGS. 5 and 6, the display substrate further includes: a first refraction layer 13 covering the region defined by the second layer of the first black matrix pattern 102, the first refraction layer 13 being arranged at a side of the third layer of the first black matrix pattern 103 close to the driving substrate; and a second refraction layer arranged at a side of the first layer of the first black matrix pattern 102 away from the driving substrate, a refractive index of the second refraction layer being greater than a refractive index of the first refraction layer 13. The second refraction layer includes a first layer of refraction layer 141 with a high refractive index arranged between the second layer of the first black matrix pattern 102 and the third layer of the first black matrix pattern 103, and a second layer of refraction layer 142 with a high refractive index arranged at a side of the third layer of the first black matrix pattern 103 away from the driving substrate. The second layer of refraction layer 142 with a high refractive index is made of a same material as the first layer of refraction layer 141 with a high refractive index.

As shown in FIG. 6, through the cooperation of the first refraction layer 13 and the second refraction layer, it is able to change light with a small angle to light with a large angle, thereby to increase the viewing angle in the direction H. As shown in FIG. 5, due to the shielding of multiple layers of the first black matrix patterns, the viewing angle in the direction V does not increase, and instead it is still maintained as a narrow viewing angle.

In the embodiments of the present disclosure, a cross section of the first refraction layer 13 in a direction perpendicular to the driving substrate is a trapezoid. As shown in FIG. 6, a side surface of the first refraction layer 13 has a gradient angle θ1 smaller than 50°. In this way, in a case that light with an emergence angle smaller than 50° reaches the side surface of the first refraction layer 13, it is converted into light with a larger angle, so as to increase the viewing angle in the direction H.

In order to increase the viewing angle in the direction H, a difference between the refractive indices of the first refraction layer 13 and the second refraction layer is greater than 0.3. The orthogonal projection of the color film layer 12 onto the driving substrate is arranged in an orthogonal projection of the first refraction layer 13 onto the driving substrate. A size of the first refraction layer 13 is greater than the size of the region defined by the second layer of the first black matrix pattern 102, and the orthogonal projection of the region defined by the second layer of the first black matrix pattern 102 onto the driving substrate is arranged in the orthogonal projection of the first refraction layer 13 onto the driving substrate.

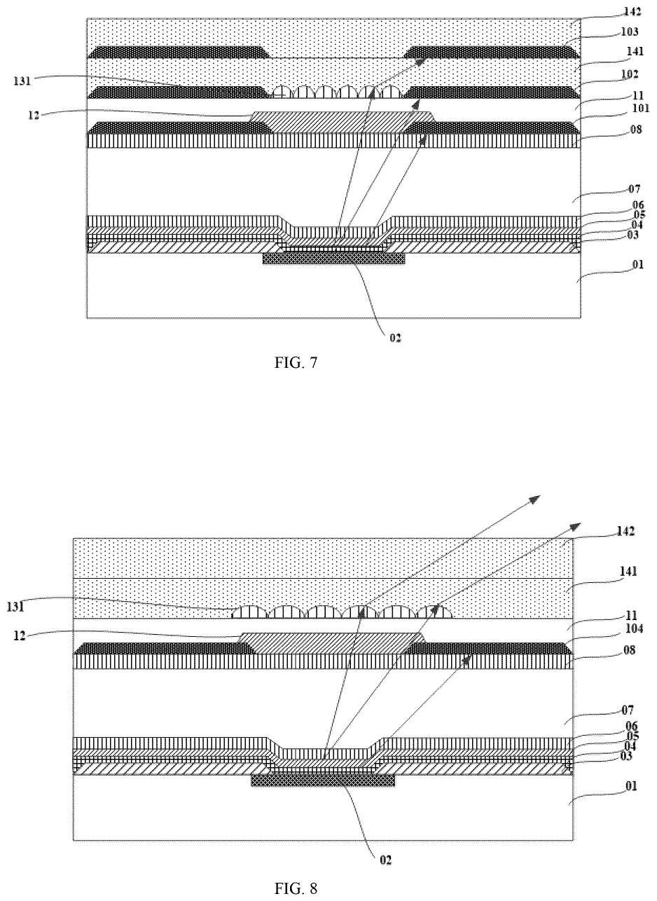

In another specific embodiment of the present disclosure, FIG. 7 is a sectional view of the display substrate in FIG. 4 in the direction H (i.e., the first direction), and FIG. 8 is a sectional view of the display substrate in FIG. 4 in the direction V (i.e., the second direction). As shown in FIGS. 7 and 8, the display substrate includes a driving substrate 01, a pixel definition layer 03 arranged on the driving substrate 01, a light-emitting element arranged in a pixel region defined by the pixel definition layer 03 and including an anode 02, a light-emitting layer 04 and a cathode 05, and an encapsulation layer arranged at a light-exiting side of the light-emitting element and including a first inorganic thin film 06, an organic thin film 07 and a second inorganic thin film 08 laminated one on another. As shown in FIG. 7, three layers of the first black matrix patterns are provided, i.e., a first layer of the first black matrix pattern 101, a second layer of the first black matrix pattern 102 and a third layer of the first black matrix pattern 103. A planarization layer 11 is arranged between the first layer of the first black matrix pattern 101 and the second layer of the first black matrix pattern 102. As shown in FIG. 8, one layer of the second black matrix pattern 104 is provided. The layer of the second black matrix pattern 104 is arranged at a same layer as the first layer of the first black matrix pattern 101, the first layer of the first black matrix pattern 101 and the layer of the second black matrix pattern 102 define a first region, a size of the first region is greater than a size of the aperture region of the light-emitting element, and the orthogonal projection of the aperture region of the light-emitting element onto the driving substrate is arranged in an orthogonal projection of the first region onto the driving substrate.

A size of the aperture region defined by the first layer of the first black matrix pattern 101 is smaller than a size of the aperture region defined by the second layer of the first black matrix pattern 102, and an orthogonal projection of the aperture region defined by the first layer of the first black matrix pattern 101 onto the driving substrate is arranged in an orthogonal projection of the aperture region defined by the second layer of the first black matrix pattern 102 onto the driving substrate. The size of the aperture region defined by the second layer of the first black matrix pattern 102 is smaller than a size of the aperture region defined by the third layer of the first black matrix pattern 103, and the orthogonal projection of the aperture region defined by the second layer of the first black matrix pattern 102 onto the driving substrate is arranged in an orthogonal projection of the aperture region defined by the third layer of the first black matrix pattern 103 onto the driving substrate.

The display substrate further includes a color film layer 12 covering the aperture region of the light-emitting element, and the orthogonal projection of the aperture region of the light-emitting element onto the driving substrate is arranged in an orthogonal projection of the color film layer 12 onto the driving substrate. Through the color film 12, it is able to achieve colorful display.

As shown in FIGS. 7 and 8, the display substrate further includes: a first refraction layer covering the region defined by the second layer of the first black matrix pattern 102, the first refraction layer including a plurality of prism members 131 arranged in an array, adjacent prism members 131 adjoining each other, the first refraction layer being arranged at a side of the third layer of the first black matrix pattern 103 close to the driving substrate; and a second refraction layer arranged at a side of the second layer of the first black matrix pattern 102 away from the driving substrate, a refractive index of the second refraction layer being greater than a refractive index of the first refraction layer. The second refraction layer includes a first layer of refraction layer 141 with a high refractive index arranged between the second layer of the first black matrix pattern 102 and the third layer of the first black matrix pattern 103, and a second layer of refraction layer 142 with a high refractive index arranged at a side of the third layer of the first black matrix pattern 103 away from the driving substrate. The second layer of refraction layer 142 with a high refractive index is made of a same material as the first layer of refraction layer 141 with a high refractive index.

As shown in FIG. 8, through the cooperation of the prism members 131 and the second refraction layer, it is able to change light with a small angle to light with a large angle, thereby to increase the viewing angle in the direction H. As shown in FIG. 7, due to the shielding of the third layer of the first black matrix pattern 103, the viewing angle in the direction V does not increase, and instead it is still maintained as a narrow viewing angle.

In order to increase the viewing angle in the direction H, a difference between the refractive indices of the prism member 131 and the second refraction layer is greater than 0.3. The orthogonal projection of the color film layer 12 onto the driving substrate is arranged in an orthogonal projection of the first refraction layer onto the driving substrate.

In the embodiments of the present disclosure, the prism member 131 is of a hemispherical or semi-ellipsoidal shape, i.e., a light-existing surface of the prism member 131 is of a hemispherical or semi-ellipsoidal shape. In a case that light with a small angle emitted by the light-emitting element reaches the light-exiting surface of the prism member 131, the angle of the light is changed to a large angle.

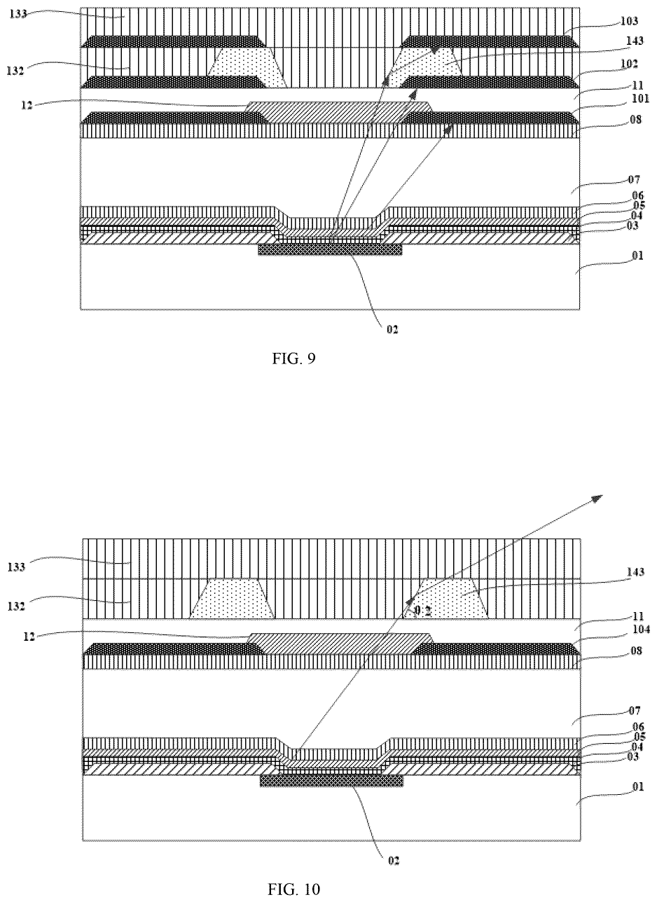

In yet another specific embodiment of the present disclosure, FIG. 9 is a sectional view of the display substrate in FIG. 4 in the direction H (i.e., the first direction), and FIG. 10 is a sectional view of the display substrate in FIG. 4 in the direction V (i.e., the second direction). As shown in FIGS. 9 and 10, the display substrate includes a driving substrate 01, a pixel definition layer 03 arranged on the driving substrate 01, a light-emitting element arranged in a pixel region defined by the pixel definition layer 03 and including an anode 02, a light-emitting layer 04 and a cathode 05, and an encapsulation layer arranged at a light-exiting side of the light-emitting element and including a first inorganic thin film 06, an organic thin film 07 and a second inorganic thin film 08 laminated one on another. As shown in FIG. 9, three layers of the first black matrix patterns are provided, i.e., a first layer of the first black matrix pattern 101, a second layer of the first black matrix pattern 102 and a third layer of the first black matrix pattern 103. A planarization layer 11 is arranged between the first layer of the first black matrix pattern 101 and the second layer of the first black matrix pattern 102. As shown in FIG. 10, one layer of the second black matrix pattern 104 is provided. The layer of the second black matrix pattern 104 is arranged at a same layer as the first layer of the first black matrix pattern 101, the first layer of the first black matrix pattern 101 and the layer of the second black matrix pattern 102 define a first region, a size of the first region is greater than a size of the aperture region of the light-emitting element, and the orthogonal projection of the aperture region of the light-emitting element onto the driving substrate is arranged in an orthogonal projection of the first region onto the driving substrate.

A size of the aperture region defined by the first layer of the first black matrix pattern 101 is smaller than a size of the aperture region defined by the second layer of the first black matrix pattern 102, and an orthogonal projection of the aperture region defined by the first layer of the first black matrix pattern 101 onto the driving substrate is arranged in an orthogonal projection of the aperture region defined by the second layer of the first black matrix pattern 102 onto the driving substrate. The size of the aperture region defined by the second layer of the first black matrix pattern 102 is smaller than a size of the aperture region defined by the third layer of the first black matrix pattern 103, and the orthogonal projection of the aperture region defined by the second layer of the first black matrix pattern 102 onto the driving substrate is arranged in an orthogonal projection of the aperture region defined by the third layer of the first black matrix pattern 103 onto the driving substrate.

The display substrate further includes a color film layer 12 covering the aperture region of the light-emitting element, and the orthogonal projection of the aperture region of the light-emitting element onto the driving substrate is arranged in an orthogonal projection of the color film layer 12 onto the driving substrate. Through the color film 12, it is able to achieve colorful display.

As shown in FIGS. 9 and 10, the display substrate further includes: a retaining wall structure 143 arranged at a side of the color film layer 12 away from the driving substrate, the retaining wall structure 143 defining a second region, a size of the second region being greater than the size of the aperture region of the light-emitting element, the orthogonal projection of the aperture region of the light-emitting element onto the driving substrate being arranged in an orthogonal projection of the second region onto the driving substrate, the retaining wall structure 143 being arranged at a side of the third layer of the first black matrix pattern 103 close to the driving substrate; and a third refraction layer arranged at a side of the retaining wall structure 143 away from the driving substrate, a refractive index of the retaining wall structure 143 being greater than a refractive index of the third refraction layer. The third refraction layer includes a first layer of refraction layer 132 with a low refractive index and a second layer of refraction layer 133 with a low refractive index, the first layer of refraction layer 132 with a low refractive index is arranged between the second layer of the first black matrix pattern 102 and the third layer of the first black matrix pattern 103, and the second layer of refraction layer 133 with a low refractive index is arranged at a side of the third layer of first black matrix pattern 103 away from the driving substrate. The first layer of refraction layer 132 with a low refractive index is made of a same material as the second layer of refraction layer 133 with a low refractive index.

As shown in FIG. 10, through the cooperation of the retaining wall structure 143 and the third refraction layer, it is able to change light with a small angle to light with a large angle, thereby to increase the viewing angle in the direction H. As shown in FIG. 9, due to the shielding of the third layer of the first black matrix pattern 103, the viewing angle in the direction V does not increase, and instead it is still maintained as a narrow viewing angle.

In order to increase the viewing angle in the direction H, a difference between the refractive indices of the retaining wall structure 143 and the third refraction layer is greater than 0.3.

In some embodiments of the present disclosure, a longitudinal section of the retaining wall structure 143 in a direction perpendicular to an extension direction of the retaining wall structure 143 is a trapezoid. As shown in FIG. 10, a lower base angle of the trapezoid is smaller than 50°. In this way, in a case that light with an emergence angle smaller than 50° reaches a side surface of the retaining wall structure 143, the angle of the light is changed to a large angle, so as to increase the viewing angle in the direction H.

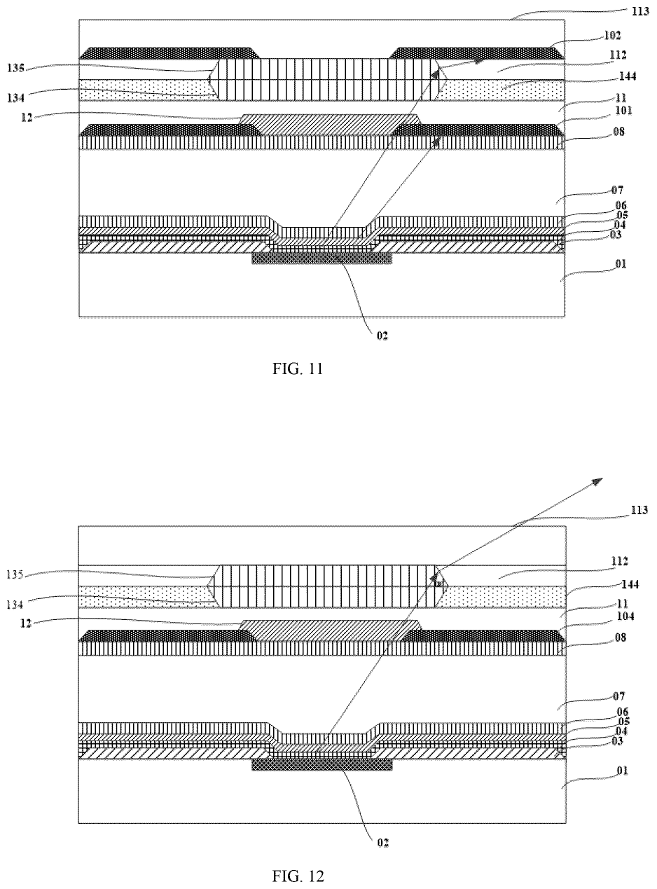

In still yet another specific embodiment of the present disclosure, FIG. 11 is a sectional view of the display substrate in FIG. 4 in the direction H (i.e., the first direction), and FIG. 12 is a sectional view of the display substrate in FIG. 4 in the direction V (i.e., the second direction). As shown in FIGS. 11 and 12, the display substrate includes a driving substrate 01, a pixel definition layer 03 arranged on the driving substrate 01, a light-emitting element arranged in a pixel region defined by the pixel definition layer 03 and including an anode 02, a light-emitting layer 04 and a cathode 05, and an encapsulation layer arranged at a light-exiting side of the light-emitting element and including a first inorganic thin film 06, an organic thin film 07 and a second inorganic thin film 08 laminated one on another. As shown in FIG. 11, two layers of the first black matrix patterns are provided, i.e., a first layer of the first black matrix pattern 101, and a second layer of the first black matrix pattern 102. A planarization layer 11 is arranged between the first layer of the first black matrix pattern 101 and the second layer of the first black matrix pattern 102. As shown in FIG. 12, one layer of the second black matrix pattern 104 is provided. The layer of the second black matrix pattern 104 is arranged at a same layer as the first layer of the first black matrix pattern 101, the first layer of the first black matrix pattern 101 and the layer of the second black matrix pattern 102 define a first region, a size of the first region is greater than a size of the aperture region of the light-emitting element, and the orthogonal projection of the aperture region of the light-emitting element onto the driving substrate is arranged in an orthogonal projection of the first region onto the driving substrate.

A size of the aperture region defined by the first layer of the first black matrix pattern 101 is smaller than a size of the aperture region defined by the second layer of the first black matrix pattern 102, and an orthogonal projection of the aperture region defined by the first layer of the first black matrix pattern 101 onto the driving substrate is arranged in an orthogonal projection of the aperture region defined by the second layer of the first black matrix pattern 102 onto the driving substrate.

The display substrate further includes a color film layer 12 covering the aperture region of the light-emitting element, and the orthogonal projection of the aperture region of the light-emitting element onto the driving substrate is arranged in an orthogonal projection of the color film layer 12 onto the driving substrate. Through the color film 12, it is able to achieve colorful display.

As shown in FIGS. 11 and 12, the display substrate further includes: a fourth refraction layer arranged at a side of the color film layer 12 away from the driving substrate, the fourth refraction layer being arranged at a side of the second layer of the first black matrix pattern 102 close to the driving substrate; and a fifth refraction layer arranged at a side of the fourth refraction layer away from the driving substrate, a refractive index of the fifth refraction layer being greater than a refractive index of the fourth refraction layer.

Through the cooperation of the fourth refraction layer and the fifth refraction layer, it is able to change light with a small angle to light with a large angle, thereby to increase the viewing angle in the direction H. Due to the shielding of the second layer of the first black matrix pattern 102, the viewing angle in the direction V does not increase, and instead it is still maintained as a narrow viewing angle.

In order to increase the viewing angle in the direction H, in some embodiments of the present disclosure, the orthogonal projection of the color film layer 12 onto the driving substrate is arranged in an orthogonal projection of the fourth refraction layer onto the driving substrate, and the orthogonal projection of the fourth refraction layer onto the driving substrate is arranged in an orthogonal projection of the fifth refraction layer onto the driving substrate.

In order to increase the viewing angle in the direction H, a difference between the refractive indices of the fifth refraction layer and the fourth refraction layer is greater than 0.3.

In some embodiments of the present disclosure, as shown in FIGS. 11 and 12, the fourth refraction layer includes a first portion 134 and a second portion 135 laminated one on another in a direction away from the driving substrate, a cross section of the first portion 134 in a direction perpendicular to the driving substrate is an inverted-trapezoid, and a cross section of the second portion 135 in the direction perpendicular to the driving substrate is a trapezoid. The fifth refraction layer includes a first film layer 112 and a second film layer 113 laminated one on another in the direction away from the driving substrate, the second film layer 113 is arranged at a side of the second layer of the first black matrix pattern 102 away from the driving substrate, and the first film layer 112 is arranged at a side of the second layer of first black matrix pattern 102 close to the driving substrate. The display substrate further includes a sixth refraction layer 144 arranged at a same layer as the first portion 134 and surrounding the first portion 134, and a refractive index of the sixth refraction layer 144 is greater than a refractive index of the first portion 134. The first film layer 112 is arranged between the sixth refraction layer 144 and the second layer of the first black matrix pattern 102, and the sixth refraction layer 144 is arranged between the first film layer 112 and the planarization layer 11.

In some embodiments of the present disclosure, as shown in FIG. 12, a lower base angle α of the trapezoid is smaller than 50°. In this way, in a case that light with an emergence angle smaller than 50° reaches a side surface of the second portion 135, the angle of the light is changed to a large angle, so as to increase the viewing angle in the direction H. In the direction V, as shown in FIG. 11, due to the shielding of the second layer of the first black matrix pattern 102, a narrow viewing angle is still provided in the direction V.

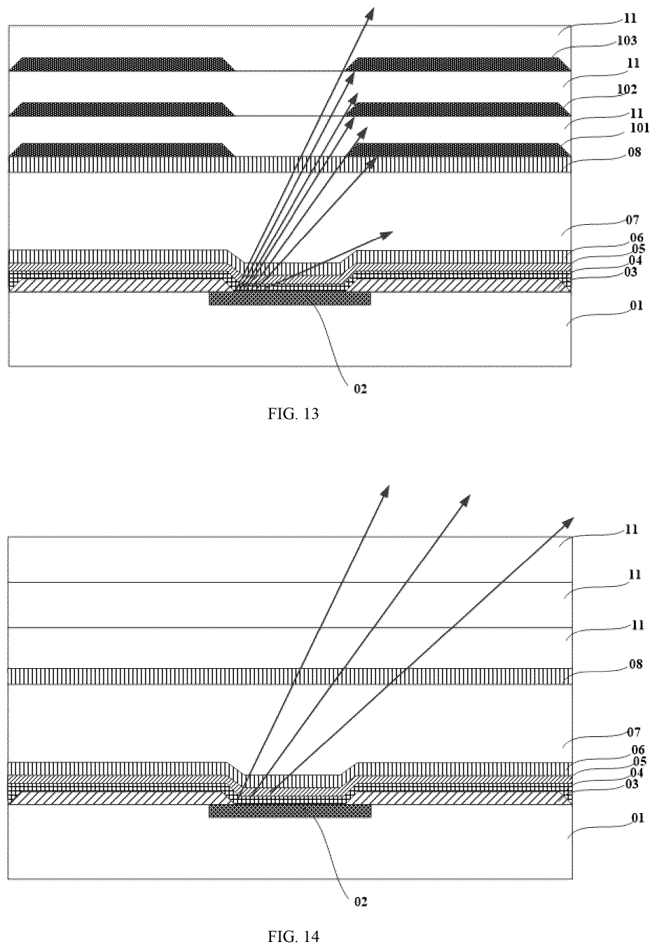

In still yet another specific embodiment of the present disclosure, FIG. 13 is a sectional view of the display substrate in FIG. 4 in the direction H (i.e., the first direction), and FIG. 14 is a sectional view of the display substrate in FIG. 4 in the direction V (i.e., the second direction). As shown in FIGS. 13 and 14, the display substrate includes a driving substrate 01, a pixel definition layer 03 arranged on the driving substrate 01, a light-emitting element arranged in a pixel region defined by the pixel definition layer 03 and including an anode 02, a light-emitting layer 04 and a cathode 05, and an encapsulation layer arranged at a light-exiting side of the light-emitting element and including a first inorganic thin film 06, an organic thin film 07 and a second inorganic thin film 08 laminated one on another. As shown in FIG. 13, three layers of the first black matrix patterns are provided, i.e., a first layer of the first black matrix pattern 101, a second layer of the first black matrix pattern 102 and a third layer of the first black matrix pattern 103. A planarization layer 11 is arranged between two adjacent layers of the first black matrix patterns. As shown in FIG. 14, no second black matrix pattern is provided, so as to ensure a large viewing angle in the direction H.

A size of the aperture region defined by the first layer of the first black matrix pattern 101 is smaller than a size of the aperture region defined by the second layer of the first black matrix pattern 102, and an orthogonal projection of the aperture region defined by the first layer of the first black matrix pattern 101 onto the driving substrate is arranged in an orthogonal projection of the aperture region defined by the second layer of the first black matrix pattern 102 onto the driving substrate. The size of the aperture region defined by the second layer of the first black matrix pattern 102 is smaller than a size of the aperture region defined by the third layer of the first black matrix pattern 103, and the orthogonal projection of the aperture region defined by the second layer of the first black matrix pattern 102 onto the driving substrate is arranged in an orthogonal projection of the aperture region defined by the third layer of the first black matrix pattern 103 onto the driving substrate.

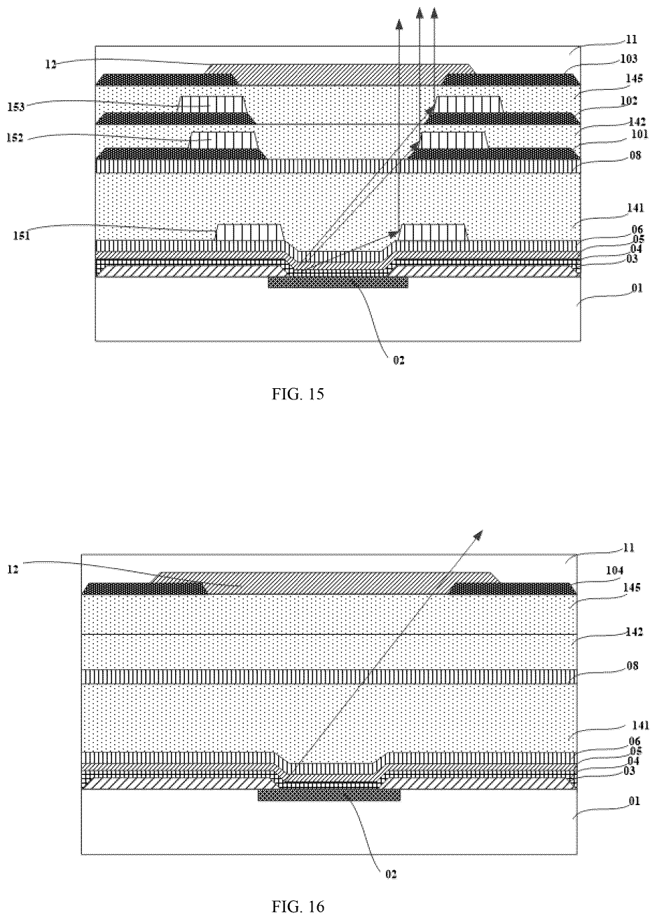

In still yet another specific embodiment of the present disclosure, FIG. 15 is a sectional view of the display substrate in FIG. 4 in the direction H (i.e., the first direction), and FIG. 16 is a sectional view of the display substrate in FIG. 4 in the direction V (i.e., the second direction). As shown in FIGS. 15 and 16, the display substrate includes a driving substrate 01, a pixel definition layer 03 arranged on the driving substrate 01, a light-emitting element arranged in a pixel region defined by the pixel definition layer 03 and including an anode 02, a light-emitting layer 04 and a cathode 05, and an encapsulation layer arranged at a light-exiting side of the light-emitting element and including a first inorganic thin film 06, an organic thin film (a first layer of refraction layer 141 with a high refractive index) and a second inorganic thin film 08 laminated one on another. As shown in FIG. 15, three layers of the first black matrix patterns are provided, i.e., a first layer of the first black matrix pattern 101, a second layer of the first black matrix pattern 102 and a third layer of the first black matrix pattern 103. A second layer of refraction layer 142 with a high refractive index is arranged between the first layer of the first black matrix pattern 101 and the second layer of the first black matrix pattern 102, and a third layer of refraction layer 145 with a high refractive index is arranged between the third layer of the first black matrix pattern 103 and the second layer of the first black matrix pattern 102.

A size of the aperture region defined by the first layer of the first black matrix pattern 101 is smaller than a size of the aperture region defined by the second layer of the first black matrix pattern 102, and an orthogonal projection of the aperture region defined by the first layer of the first black matrix pattern 101 onto the driving substrate is arranged in an orthogonal projection of the aperture region defined by the second layer of the first black matrix pattern 102 onto the driving substrate. The size of the aperture region defined by the second layer of the first black matrix pattern 102 is smaller than a size of the aperture region defined by the third layer of the first black matrix pattern 103, and the orthogonal projection of the aperture region defined by the second layer of the first black matrix pattern 102 onto the driving substrate is arranged in an orthogonal projection of the aperture region defined by the third layer of the first black matrix pattern 103 onto the driving substrate.

The display substrate further includes a color film layer 12 covering the aperture region of the light-emitting element, and the orthogonal projection of the aperture region defined by the third layer of the first black matrix pattern 103 onto the driving substrate is arranged in an orthogonal projection of the color film layer 12 onto the driving substrate. Through the color film 12, it is able to achieve colorful display.

The display substrate further includes a transparent retaining wall extending in the first direction. A refractive index of the transparent retaining wall is smaller than a refractive index of a seventh refraction layer (including the first layer of refraction layer 141 with a high refractive index, the second layer of refraction layer 142 with a high refractive index, and the third layer of refraction layer 145 with a high refractive index). The transparent retaining wall is arranged at two sides of the aperture region, and/or the transparent retaining wall is arranged at two sides of the region defined by the first black matrix pattern.

As shown in FIG. 15, the transparent retaining wall includes: a first layer of the transparent retaining wall 151 arranged at two sides of the aperture region of the light-emitting element; a second layer of the transparent retaining wall 152 arranged at two sides of the region defined by the first layer of the first black matrix pattern 101; and a third layer of the transparent retaining wall 153 arranged at two sides of a region defined by the second layer of the first black matrix pattern 102.

Through the cooperation of the transparent retaining wall and the seventh refraction layer, as shown in FIG. 15, a direction of part of the light with a large angle is changed due to total reflection, and the light exits upward, so as to improve the luminous efficiency of the display substrate, and reduce the power consumption.

In order to increase the luminous efficiency of the display substrate and reduce the power consumption of the product, a difference between the refractive indices of the transparent retaining wall and the seventh refraction layer is greater than 0.3.

As shown in FIG. 16, the display substrate merely includes one layer of the second black matrix pattern 104, and a large viewing angle is still provided in the direction H.

The present disclosure further provides in some embodiments a display device, which includes the above-mentioned display substrate.

The display device includes, but not limited to, a radio frequency unit, a network module, an audio output unit, an input unit, a sensor, a display unit, a user input unit, an interface unit, a memory, a processor, and a power source. It should be appreciated that, the display device may not be limited thereto, i.e., it may include more or fewer members, or some members may be combined, or the members may be arranged in different modes. In the embodiments of the present disclosure, the display device may include, but not limited to, display, mobile phone, flat-panel computer, television, wearable electronic device or navigator.

The display device may be any product or member having a display function, e.g., television, display, digital photo frame, mobile phone, or tablet computer. The display device further includes a flexible circuit board, a printed circuit board and a back plate. The display device in the embodiments of the present disclosure may be applied to a vehicle-mounted display product, so as to provide a wide viewing angle in the direction H and a narrow viewing angle in the direction V.

The present disclosure further provides in some embodiments a method for manufacturing a display substrative, which includes: providing a driving substrate; forming a plurality of light-emitting elements arranged in an array on the driving substrate; forming an encapsulation layer at a light-exiting side of the light-emitting element; and forming a black matrix structure at a side of the encapsulation layer away from the driving substrate. The black matrix structure includes at least two layers of first black matrix patterns arranged sequentially in a light-exiting direction of the light-emitting element, and the first black matrix pattern extends in a first direction. In the light-exiting direction of the light-emitting element, an orthogonal projection of an aperture region of the light-emitting element onto the driving substrate is arranged in a region defined by a first layer of the first black matrix patterns, and an orthogonal projection of a region defined by a former layer of the first black matrix patterns onto the driving substrate is arranged in an orthogonal projection of a region defined by a latter layer of the first black matrix patterns onto the driving substrate.

In the embodiments of the present disclosure, at least two layers of the first black matrix patterns are arranged at the light-exiting side of the light-emitting element, the first black matrix pattern extends in the first direction, and light emitted by the light-emitting element in a direction intersecting the first direction is shielded by the first black matrix pattern. As a result, a viewing angle in the direction intersecting the first direction is narrowed, so that the light-emitting element is provided with a viewing angle in the first direction different from that in the other direction.

The method in the embodiments of the present disclosure is used to manufacture the display substrate as shown in FIGS. 5 to 16. In the embodiments of the present disclosure, through adjusting the size of the region defined by the first black matrix pattern, the viewing angle in a direction intersecting the first direction may be adjusted. The smaller the size of the region defined by the first black matrix pattern, the narrower the viewing angle in the direction intersecting the first direction; the larger the size of the region defined by the first black matrix pattern, the larger the viewing angle in the direction intersecting the first direction.

In some embodiments of the present disclosure, the forming the black matrix structure further includes forming at least one layer of a second black matrix pattern sequentially in the light-exiting direction of the light-emitting element. The second black matrix pattern extends in a second direction, the orthogonal projection of the aperture region of the light-emitting element onto the driving substrate is arranged in a region defined by the second black matrix pattern, the second direction intersects the first direction, and the quantity of layers of the second black matrix patterns is smaller than the quantity of layers of the first black matrix patterns.

In the embodiments of the present disclosure, at least one layer of the second black matrix pattern is further arranged at the light-exiting side of the light-emitting element, and the second black matrix pattern extends in the second direction. In this way, the light emitting by the light-emitting element in a direction intersecting the second direction is shielded by the first black matrix pattern, so as to narrow the viewing angle in the direction intersecting the second direction. In the embodiments of the present disclosure, through adjusting the size of the region defined by the second black matrix pattern, the viewing angle in the direction intersecting the second direction may be adjusted. The smaller the size of the region defined by the second black matrix pattern, the narrower the viewing angle in the direction intersecting the second direction; the larger the size of the region defined by the second black matrix pattern, the wider the viewing angle in the direction intersecting the second direction.

In some embodiments of the present disclosure, the first direction is perpendicular to the second direction. In this way, through adjusting the size of the region defined by the second black matrix pattern, the viewing angle int eh first direction may be adjusted. The smaller the size of the region defined by the second black matrix pattern, the narrower the viewing angle in the first direction; the larger the size of the region defined by the second black matrix pattern, the wider the viewing angle in the first direction. Through adjusting the size of the region defined by the first black matrix pattern, the viewing angle in the second direction may be adjusted. The smaller the size of the region defined by the first black matrix pattern, the narrower the viewing angle in the second direction; the larger the size of the region defined by the first black matrix pattern, the wider the viewing angle in the second direction.

In the embodiments of the present disclosure, through adjusting the size of the region defined by the second black matrix pattern and/or the size of the region defined by the first black matrix pattern, it is able to adjust the viewing angle in the first direction and/or the second direction, thereby to provide a display device with different viewing angles in different directions, and meet the requirements on the viewing angles in different directions.

In the embodiments of the present disclosure, the quantity of layers of the first black matrix patterns and the layers of the second black matrix patterns may be set according to the practical need. In some embodiments of the present disclosure, in a case that the viewing angle in the first direction needs to be narrowed and the viewing angle in the second direction needs to be broadened, the black matrix structure includes three layers of the first black matrix patterns and one layer of the second black matrix pattern arranged sequentially in the light-exiting direction of the light-emitting element. Of course, the black matrix structure is not limited to three layers of the first black matrix patterns and one layer of the second black matrix pattern, and it may include more layers of the first black matrix patterns or more layers of the second black matrix patterns. Usually, the more the layers of the first black matrix patterns, the narrower the viewing angle in the second direction; the more the layers of the second black matrix patterns, the narrower the viewing angle in the first direction.

It should be appreciated that, the above embodiments have been described in a progressive manner, and the same or similar contents in the embodiments have not been repeated, i.e., each embodiment has merely focused on the difference from the others. Especially, the method embodiments are substantially similar to the product embodiments, and thus have been described in a simple manner.

Unless otherwise defined, any technical or scientific term used herein shall have the common meaning understood by a person of ordinary skills. Such words as “first” and “second” used in the specification and claims are merely used to differentiate different components rather than to represent any order, number of importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

It should be appreciated that, in the case that such an element as layer, film, region or substrate is arranged “on” or “under” another element, it may be directly arranged “on” or “under” the other element, or an intermediate element may be arranged therebetween.

In the above description, the features, structures, materials or characteristics may be combined in any embodiment or embodiments in an appropriate manner.

The above embodiments are merely for illustrative purposes, but shall not be construed as limiting the scope of the present disclosure. Any person skilled in the art may make modifications and substitutions without departing from the spirit of the present disclosure, and these modifications and substitutions shall also fall within the scope of the present disclosure. Hence, the scope of the present disclosure shall be subject to the scope defined by the appended claims.

1. A display substrate, comprising:
a driving substrate;
a plurality of light-emitting elements arranged in an array on the driving substrate;
an encapsulation layer arranged at a light-exiting side of the light-emitting element; and
a black matrix structure arranged at a side of the encapsulation layer away from the driving substrate; wherein the black matrix structure comprises at least two layers of first black matrix patterns arranged sequentially in a light-exiting direction of the light-emitting element, and the first black matrix pattern extends in a first direction;
wherein in the light-exiting direction of the light-emitting element, an orthogonal projection of an aperture region of the light-emitting element onto the driving substrate is arranged in a region defined by a first layer of the first black matrix pattern, and an orthogonal projection of a region defined by a former layer of the first black matrix pattern onto the driving substrate is arranged in an orthogonal projection of a region defined by a latter layer of the first black matrix pattern onto the driving substrate.

2. The display substrate according to claim 1, wherein the black matrix structure comprises three layers of the first black matrix patterns arranged sequentially in the light-exiting direction of the light-emitting element;
or,
wherein the black matrix structure further comprises at least one layer of a second black matrix pattern arranged sequentially in the light-exiting direction of the light-emitting element; the second black matrix pattern extends in a second direction, an orthogonal projection of the aperture region of the light-emitting element onto the driving substrate is arranged in a region defined by the second black matrix pattern, the second direction intersects the first direction, and a quantity of layers of the second black matrix patterns is smaller than a quantity of layers of the first black matrix patterns.

3. (canceled)

4. The display substrate according to claim 2, wherein the first direction is perpendicular to the second direction:
or,
wherein the black matrix structure comprises one layer of the second black matrix pattern.

5. (canceled)

6. The display substrate according to claim 2, wherein the first layer of the first black matrix pattern is arranged at a same layer as a first layer of the second black matrix pattern, the first layer of the first black matrix pattern and the first layer of the second black matrix pattern define a first region, and the orthogonal projection of the aperture region of the light-emitting element onto the driving substrate is arranged in an orthogonal projection of the first region onto the driving substrate.

7. The display substrate according to claim 1, further comprising a color film layer covering the aperture region of the light-emitting element, wherein the orthogonal projection of the light-emitting element onto the driving substrate is arranged in an orthogonal projection of the color film layer onto the driving substrate.

8. The display substrate according to claim 7, further comprising:
a first refraction layer covering a region defined by a second layer of the first black matrix pattern, the first refraction layer being arranged at a side of an outermost layer of the first black matrix pattern close to the driving substrate; and
a second refraction layer arranged at a side of the first refraction layer away from the driving substrate, a refractive index of the second refraction layer being greater than a refractive index of the first refraction layer.

9. The display substrate according to claim 8, wherein a side surface of the first refraction layer has a gradient angle smaller than 50°;
or,
wherein the orthogonal projection of the color film layer onto the driving substrate is arranged in an orthogonal projection of the first refraction layer onto the driving substrate.

10. (canceled)

11. The display substrate according to claim 8, wherein the first refraction layer comprises a plurality of prism members arranged in an array, and adjacent prism members adjoin each other.

12. The display substrate according to claim 11, wherein the prism member is of a hemispherical shape.

13. The display substrate according to claim 7, further comprising:
a retaining wall structure arranged at a side of the color film layer away from the driving substrate; wherein the retaining wall structure defines a second region, the orthogonal projection of the aperture region of the light-emitting element onto the driving substrate is arranged in an orthogonal projection of the second region onto the driving substrate, the retaining wall structure is arranged at a side of the outermost layer of the first black matrix pattern close to the driving substrate; and
a third refraction layer arranged at a side of the retaining wall structure away from the driving substrate; wherein a refractive index of the retaining wall structure is greater than a refractive index of the third refraction layer.

14. The display substrate according to claim 13, wherein a longitudinal section of the retaining wall structure in a direction perpendicular to an extension direction of the retaining wall structure is a trapezoid.

15. The display substrate according to claim 7, further comprising:
a fourth refraction layer arranged at a side of the color film layer away from the driving substrate; wherein the fourth refraction layer is arranged at a side of the outermost layer of the first black matrix pattern close to the driving substrate; and
a fifth refraction layer arranged at a side of the fourth refraction layer away from the driving substrate; wherein a refractive index of the fifth refraction layer is greater than a refractive index of the fourth refraction layer.

16. The display substrate according to claim 15, wherein the orthogonal projection of the color film layer onto the driving substrate is arranged in an orthogonal projection of the fourth refraction layer onto the driving substrate; and
the orthogonal projection of the fourth refraction layer onto the driving substrate is arranged in an orthogonal projection of the fifth refraction layer onto the driving substrate.

17. The display substrate according to claim 15, wherein the fourth refraction layer comprises a first portion and a second portion laminated one on another in a direction away from the driving substrate, a cross section of the first portion in a direction perpendicular to the driving substrate is an inverted-trapezoid, and a cross section of the second portion in the direction perpendicular to the driving substrate is a trapezoid.

18. The display substrate according to claim 17, further comprising a sixth refraction layer arranged at a same layer as the first portion and surrounding the first portion, wherein a refractive index of the sixth refraction layer is greater than a refractive index of the first portion.

19. The display substrate according to claim 17, wherein a lower base angle of the trapezoid is smaller than 50°.

20. The display substrate according to claim 1, further comprising:
a seventh refraction layer arranged between two adjacent layers of the first black matrix patterns; and
a transparent retaining wall extending in the first direction; wherein a refractive index of the transparent retaining wall is smaller than a refractive index of the seventh refraction layer, the transparent retaining wall is arranged at two sides of the aperture region, and/or the transparent retaining wall is arranged at two sides of the region defined by the first black matrix pattern.

21. The display substrate according to claim 20, wherein the transparent retaining wall comprises:
a first layer of the transparent retaining wall arranged at two sides of the aperture region of the light-emitting element;
a second layer of the transparent retaining wall arranged at two sides of the region defined by the first layer of the first black matrix pattern; and
a third layer of the transparent retaining wall arranged at two sides of a region defined by a second layer of the first black matrix pattern.

22. A display device, comprising a display substrate;
wherein the display substrate comprises:
a driving substrate:
a plurality of light-emitting elements arranged in an array on the driving substrate;
an encapsulation layer arranged at a light-exiting side of the light-emitting element; and
a black matrix structure arranged at a side of the encapsulation layer away from the driving substrate; wherein the black matrix structure comprises at least two layers of first black matrix patterns arranged sequentially in a light-exiting direction of the light-emitting element, and the first black matrix pattern extends in a first direction;
wherein in the light-exiting direction of the light-emitting element, an orthogonal projection of an aperture region of the light-emitting element onto the driving substrate is arranged in a region defined by a first layer of the first black matrix pattern, and an orthogonal projection of a region defined by a former layer of the first black matrix pattern onto the driving substrate is arranged in an orthogonal projection of a region defined by a latter layer of the first black matrix pattern onto the driving substrate.

23. A method for manufacturing a display substrate, comprising:
providing a driving substrate;
forming a plurality of light-emitting elements arranged in an array on the driving substrate;
forming an encapsulation layer at a light-exiting side of the light-emitting element; and
forming a black matrix structure at a side of the encapsulation layer away from the driving substrate; wherein the black matrix structure comprises at least two layers of first black matrix patterns arranged sequentially in a light-exiting direction of the light-emitting element, and the first black matrix pattern extends in a first direction;
wherein in the light-exiting direction of the light-emitting element, an orthogonal projection of an aperture region of the light-emitting element onto the driving substrate is arranged in a region defined by a first layer of the first black matrix patterns, and an orthogonal projection of a region defined by a former layer of the first black matrix patterns onto the driving substrate is arranged in an orthogonal projection of a region defined by a latter layer of the first black matrix patterns onto the driving substrate.
